(19) United States
(12) Patent Application Publication
(10) Pub. No.: US 2023/0344243 A1
(43) Pub. Date: Oct. 26, 2023

(54) BATTERY AUTHENTICITY DETERMINATION METHOD, BATTERY AUTHENTICITY DETERMINATION DEVICE, AND COMPUTER-READABLE RECORDING MEDIUM RECORDING A PROGRAM

(71) Applicant: Panasonic Intellectual Property Corporation of America, Torrance, CA (US)

(72) Inventor: Nobuaki TASAKI, Osaka (JP)

(73) Assignee: Panasonic Intellectual Property Corporation of America, Torrance, CA (US)

(21) Appl. No.: 18/217,066

(22) Filed: Jun. 30, 2023

Related U.S. Application Data
(63) Continuation of application No. PCT/JP2021/033871, filed on Sep. 15, 2021.

(30) Foreign Application Priority Data
Jan. 6, 2021 (JP) 2021-000865

(51) Int. Cl. H02J 7/00

(52) U.S. Cl. CPC H02J 7/00045; H02J 7/00034; H02J 7/0049

(57) ABSTRACT

An acquisition unit acquires, regarding a battery that is a determination target, first data indicating a charge-discharge history in a first period and second data indicating a charge-discharge history in a second period before the first period, a calculation unit calculates a first state quantity indicating a state quantity of the battery in the first period based on the first data, and calculates a second state quantity indicating an estimated value of the state quantity of the battery in the first period based on the second data, a determination unit performs authenticity determination as to whether the battery is a genuine product or an imitation product in the first period based on the first state quantity and the second state quantity, and an output unit outputs a result of the authenticity determination.

### TECHNICAL FIELD

The present disclosure relates to a battery authenticity determination method, a battery authenticity determination device, and a computer-readable recording medium recording a program.

### BACKGROUND ART

Patent Literature 1 listed below discloses a battery authentication system that determines authenticity of a battery based on a battery pack ID given to an ECU of the battery pack.

According to the battery authentication system disclosed in Patent Literature 1, when only the battery cell is replaced with an imitation product, the battery cannot be correctly determined as an imitation product.

### CITATION LIST

### Patent Literature

Patent Literature 1: JP 2012-222945 A

### SUMMARY OF INVENTION

An object of the present disclosure is to provide a technique capable of correctly determining a battery as an imitation product even when only a battery cell is replaced with the imitation product.

A battery authenticity determination method according to an aspect of the present disclosure includes, by a computer: acquiring, regarding a battery that is a determination target, first data indicating a charge-discharge history in a first period and second data indicating a charge-discharge history in a second period before the first period; calculating a first state quantity indicating a state quantity of the battery in the first period based on the first data; calculating a second state quantity indicating an estimated value of the state quantity of the battery in the first period based on the second data; performing authenticity determination as to whether the battery is a genuine product or an imitation product in the first period based on the first state quantity and the second state quantity; and outputting a result of the authenticity determination.

### BRIEF DESCRIPTION OF DRAWINGS

FIG. 1 is a block diagram illustrating in a simplified manner a configuration of a battery management system according to an embodiment of the present disclosure.

FIG. 2 is a flowchart illustrating a first example of authenticity determination processing executed by a server device.

FIG. 3 is a view illustrating an example of a time series change in a full charge capacity value of a battery pack.

FIG. 4 is a flowchart illustrating a second example of authenticity determination processing executed by the server device.

FIG. 5 is a view illustrating an example of distribution of OCV values in accordance with an SOC of a battery pack.

FIG. 6 is a flowchart illustrating a third example of authenticity determination processing executed by the server device.

FIG. 7 is a view illustrating a voltage drop that occurs with discharge operation of a battery pack.

FIG. 8 is a view illustrating an example of distribution of a drop voltage value in accordance with an SOC and a discharge current rate of the battery pack.

FIG. 9 is a flowchart illustrating a fourth example of authenticity determination processing executed by the server device.

FIG. 10 is a view illustrating a first modification of the system configuration.

FIG. 11 is a view illustrating a second modification of the system configuration.

FIG. 12 is a view illustrating a third modification of the system configuration.

### DESCRIPTION OF EMBODIMENTS

(Knowledge Underlying Present Disclosure)

Since genuine battery packs used in electric motorcycles and the like are expensive and resale is possible, it is expected that imitation products will be widely distributed. In order to prevent occurrence of an accident, a vehicle failure, or the like caused by use of a poor imitation product and to maintain fair prices of genuine products, it is necessary to suppress distribution of imitation products in the market.

Patent Literature 1 discloses a battery authentication system that targets a battery mounted on an electric vehicle. In the system, an immobilizer unit compares a first battery pack ID stored in a memory of the ECU included in the battery pack with a second battery pack ID stored in a memory of the ECU included in a vehicle, permits activation of the vehicle when the battery pack IDs match, and inhibits activation of the vehicle when the battery pack IDs do not match.

However, according to the battery authentication system disclosed in Patent Literature 1, when only a battery cell is replaced with an imitation product while using an ECU of a genuine product in the battery pack, the first battery pack ID stored in the memory of the ECU does not change, and therefore the immobilizer unit erroneously determines the battery pack as a genuine product.

In order to solve such a problem, the present inventor has found that by recording a charge-discharge history of a battery and determining authenticity of the battery based on a state quantity of the battery that can be calculated from the charge-discharge history, it is possible to detect replacement of a battery cell due to a sudden great change in the state quantity, and has conceived of the present disclosure.

Next, each aspect of the present disclosure will be described.

A battery authenticity determination method according to an aspect of the present disclosure includes, by a computer: acquiring, regarding a battery having a battery cell, first data indicating a charge-discharge history in a first period and second data indicating a charge-discharge history in a second period before the first period; calculating a first state quantity indicating a state quantity of the battery in the first period based on the first data; calculating a second state quantity indicating an estimated value of the state quantity of the battery in the first period based on the second data; performing authenticity determination as to whether the battery is a genuine product or an imitation product in the first period based on the first state quantity and the second state quantity; and outputting a result of the authenticity determination.

According to this aspect, the first state quantity indicating the state quantity of the battery in the first period is calculated based on the first data, and the second state quantity indicating an estimated value of the state quantity of the battery in the first period is calculated based on the second data. When a battery cell of a genuine product is replaced with an imitation product, the first state quantity and the second state quantity greatly differ before and after replacement, and therefore by performing authenticity determination of the battery based on the first state quantity and the second state quantity, it is possible to detect that the battery cell has been replaced. As a result, even when only the battery cell is replaced with an imitation product, the battery can be correctly determined as an imitation product.

In the above aspect, the state quantity includes a full charge capacity.

According to this aspect, since it is possible to accurately calculate the full charge capacity of the battery based on the charge-discharge history of the battery, it becomes possible to improve the accuracy of determination by performing authenticity determination of the battery based on the full charge capacity of the battery.

In the above aspect, in calculating the first state quantity, a plurality of full charge capacity values are calculated by calculating the full charge capacity every time the battery is fully charged in the first period based on the first data, in calculating the second state quantity, an estimated value of the full charge capacity of the battery in the first period and an allowable upper limit value and an allowable lower limit value having the estimated value therebetween are calculated based on the second data, and in the authenticity determination, a ratio of a number of full charge capacity values exceeding the allowable upper limit value or below the allowable lower limit value to a total number of the plurality of full charge capacity values in the first period is calculated as a suspect rate that the battery is an imitation product.

According to this aspect, it becomes possible to output, as a result of authenticity determination, the suspect rate indicating the probability that the battery is an imitation product, instead of alternative of whether the battery is a genuine product or an imitation product.

In the above aspect, the state quantity includes open circuit voltage in accordance with a remaining capacity rate.

According to this aspect, since it is possible to accurately calculate the open circuit voltage in accordance with the remaining capacity rate of the battery based on the charge-discharge history of the battery, it becomes possible to improve the accuracy of determination by performing authenticity determination of the battery based on the open circuit voltage in accordance with the remaining capacity rate of the battery.

In the above aspect, in calculating the first state quantity, a plurality of open circuit voltage values is calculated by calculating the open circuit voltage every time the battery is charged in the first period based on the first data, in calculating the second state quantity, an estimated value of the open circuit voltage in the first period and an allowable upper limit value and an allowable lower limit value having the estimated value therebetween are calculated based on the second data, and in the authenticity determination, a ratio of a number of the open circuit voltage values exceeding the allowable upper limit value or below the allowable lower limit value to a total number of the plurality of open circuit voltage values in the first period is calculated as a suspect rate that the battery is an imitation product.

According to this aspect, it becomes possible to output, as a result of authenticity determination, the suspect rate indicating the probability that the battery is an imitation product, instead of alternative of whether the battery is a genuine product or an imitation product.

In the above aspect, the state quantity includes a drop voltage in accordance with a remaining capacity rate and a discharge current rate.

According to this aspect, since it is possible to accurately calculate the drop voltage in accordance with the remaining capacity rate and the discharge current rate of the battery based on the charge-discharge history of the battery, it becomes possible to improve the accuracy of determination by performing authenticity determination of the battery based on the drop voltage in accordance with the remaining capacity rate and the discharge current rate of the battery.

In the above aspect, in calculating the first state quantity, a plurality of drop voltage values are calculated by calculating the drop voltage every time the battery is discharged in the first period based on the first data, in calculating the second state quantity, an estimated value of the drop voltage in the first period and an allowable upper limit value and an allowable lower limit value having the estimated value therebetween are calculated based on the second data, and in the authenticity determination, a ratio of a number of the drop voltage values exceeding the allowable upper limit value or below the allowable lower limit value to a total number of the plurality of drop voltage values in the first period is calculated as a suspect rate that the battery is an imitation product.

According to this aspect, it becomes possible to output, as a result of authenticity determination, the suspect rate indicating the probability that the battery is an imitation product, instead of alternative of whether the battery is a genuine product or an imitation product.

A battery authenticity determination device according to an aspect of the present disclosure includes: an acquisition unit that acquires, regarding a battery having a battery cell, first data indicating a charge-discharge history in a first period and second data indicating a charge-discharge history in a second period before the first period; a calculation unit that calculates a first state quantity indicating a state quantity of the battery in the first period based on the first data, and calculates a second state quantity indicating an estimated value of the state quantity of the battery in the first period based on the second data; a determination unit that performs authenticity determination as to whether the battery is a genuine product or an imitation product in the first period based on the first state quantity and the second state quantity; and an output unit that outputs a result of the authenticity determination.

According to this aspect, the calculation unit calculates the first state quantity indicating the state quantity of the battery in the first period based on the first data, and calculates the second state quantity indicating the estimated value of the state quantity of the battery in the first period based on the second data. When a battery cell of a genuine product is replaced with an imitation product, the first state quantity and the second state quantity greatly differ before and after replacement, and therefore by the determination unit performing authenticity determination of the battery based on the first state quantity and the second state quantity, it is possible to detect that the battery cell has been replaced. As a result, even when only the battery cell is replaced with an imitation product, the battery can be correctly determined as an imitation product.

A program according to an aspect of the present disclosure is a program for causing a computer to function as: acquisition means for acquiring, regarding a battery having a battery cell, first data indicating a charge-discharge history in a first period and second data indicating a charge-discharge history in a second period before the first period; calculation means for calculating a first state quantity indicating a state quantity of the battery in the first period based on the first data, and calculates a second state quantity indicating an estimated value of the state quantity of the battery in the first period based on the second data; determination means for performing authenticity determination as to whether the battery is a genuine product or an imitation product in the first period based on the first state quantity and the second state quantity, and output means for outputting a result of the authenticity determination.

According to this aspect, the calculation means calculates the first state quantity indicating the state quantity of the battery in the first period based on the first data, and calculates the second state quantity indicating the estimated value of the state quantity of the battery in the first period based on the second data. When a battery cell of a genuine product is replaced with an imitation product, the first state quantity and the second state quantity greatly differ before and after replacement, and therefore by the determination means performing authenticity determination of the battery based on the first state quantity and the second state quantity, it is possible to detect that the battery cell has been replaced. As a result, even when only the battery cell is replaced with an imitation product, the battery can be correctly determined as an imitation product.

The present disclosure can be implemented as a computer program for causing a computer to execute each characteristic configuration included in such a method, or can be implemented as a device or a system that operates based on this computer program. It goes without saying that such a computer program can be distributed as a computer-readable non-volatile recording medium such as a CD-ROM, or distributed via a communication network such as the Internet.

Each embodiment described below shows a specific example of the present disclosure. Numerical values, shapes, components, steps, order of steps, and the like shown in the following embodiment are merely examples, and are not intended to limit the present disclosure. The components in the following embodiment include a component that is not described in an independent claim indicating the highest concept and that is described as an arbitrary component. In all the embodiments, respective contents can be combined.

### Embodiment of Present Disclosure

Hereinafter, an embodiment of the present disclosure will be described in detail with reference to the drawings. Elements denoted by the same reference numerals in different drawings represent the same or corresponding elements.

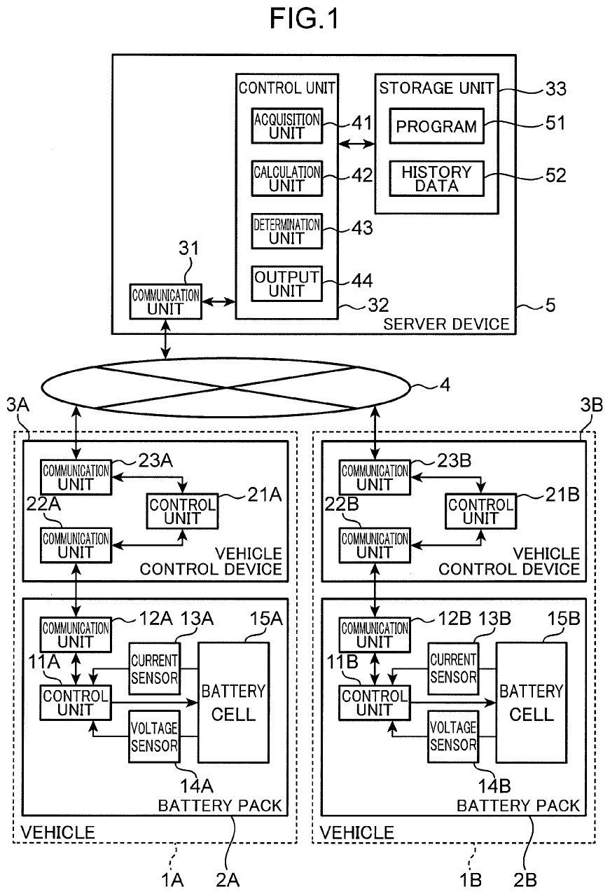

FIG. 1 is a block diagram illustrating in a simplified manner the configuration of a battery management system according to an embodiment of the present disclosure. In the example of the present embodiment, the battery management system manages a plurality of battery packs 2A and 2B mounted on a plurality of vehicles 1A and 1B such as electric motorcycles.

The battery management system includes a server device 5 connected to a communication network 4. The communication network 4 is, for example, a public network. The server device 5 is, for example, a cloud server, and functions as an authenticity determination device in the system configuration according to the present embodiment.

The server device 5 includes a communication unit 31, a control unit 32, and a storage unit 33. The communication unit 31 is configured using a communication module for performing wireless communication by an arbitrary communication method such as IP. The storage unit 33 is configured using a hard disk, an SSD, a semiconductor memory, or the like. The storage unit 33 stores a program 51 and history data 52. The control unit 32 is configured using a data processing device such as a CPU. As functions implemented by the CPU executing the program 51, the control unit 32 includes an acquisition unit 41, a calculation unit 42, a determination unit 43, and an output unit 44.

The vehicle 1A includes a battery pack 2A and a vehicle control device 3A. The battery pack 2A supplies electric power for driving a traveling motor or the like mounted on the vehicle 1A. The battery pack 2A can be charged by a plug-in method by receiving power supply from a commercial power source or the like externally connected to the vehicle 1A.

The battery pack 2A includes a control unit 11A, a communication unit 12A, a current sensor 13A, a voltage sensor 14A, and a battery cell 15A. The control unit 11A is configured using a data processing device such as a CPU. The communication unit 12A is configured using a communication module for performing wireless communication by an arbitrary communication method such as Bluetooth (registered trademark). The battery cell 15A is configured using a rechargeable secondary battery such as a lithium ion battery. The current sensor 13A detects a current value of the charge-discharge current (charge current and discharge current) of the battery cell 15A, and outputs current value data indicating the detected current value. The voltage sensor 14A detects a voltage value between both poles (positive electrode and negative electrode) of the battery cell 15A, and outputs voltage value data indicating the detected voltage value.

The vehicle control device 3A is configured using a part of a function of, for example, a navigation device of the vehicle 1A. The vehicle control device 3A includes a control unit 21A and communication units 22A and 23A. The control unit 21A is configured using a data processing device such as a CPU. The communication unit 22A is configured using a communication module for performing wireless communication with the communication unit 12A of the battery pack 2A by an arbitrary communication method such as Bluetooth (registered trademark). The communication unit 23A is configured using a communication module for performing wireless communication with the communication unit 31 of the server device 5 by an arbitrary communication method such as IP.

The configuration of the vehicle 1B is similar to the configuration of the vehicle 1A. The vehicle 1B includes a battery pack 2B and a vehicle control device 3B. The battery pack 2B includes a control unit 11B, a communication unit 12B, a current sensor 13B, a voltage sensor 14B, and a battery cell 15B. The vehicle control device 3B includes a control unit 21B and communication units 22B and 23B.

In the battery management system according to the present embodiment, the server device 5 manages the battery packs 2A and 2B mounted on the vehicles 1A and 1B. The battery packs 2A and 2B are given battery pack IDs, which are identification information for individually identifying the plurality of battery packs.

When a charge-discharge current flows through the battery cell 15A, current value data is input from the current sensor 13A to the control unit 11A, and voltage value data is input from the voltage sensor 14A to the control unit 11A. The control unit 11A inputs current value data and voltage value data to the communication unit 12A. This current value data and the voltage value data include the battery pack ID of the battery pack 2A. The communication unit 12A transmits current value data and voltage value data to the vehicle control device 3A. The communication unit 22A of the vehicle control device 3A receives current value data and voltage value data, and inputs the received current value data and voltage value data to the control unit 21A. The control unit 21A inputs current value data and voltage value data to the communication unit 23A. The communication unit 23A transmits current value data and voltage value data to the server device 5. The communication unit 31 of the server device 5 receives current value data and voltage value data, and inputs the received current value data and voltage value data to the control unit 32. The control unit 32 stores current value data and voltage value data in the storage unit 33 in association with the battery pack ID of the battery pack 2A included therein. Similarly to the vehicle 1A, also in the vehicle 1B, the control unit 32 stores current value data and voltage value data in the storage unit 33 in association with the battery pack ID of the battery pack 2B. In this manner, the history data 52 indicating the charge-discharge history of each of the battery packs 2A and 2B in association with the battery pack ID of each of the battery packs 2A and 2B is accumulated in the storage unit 33.

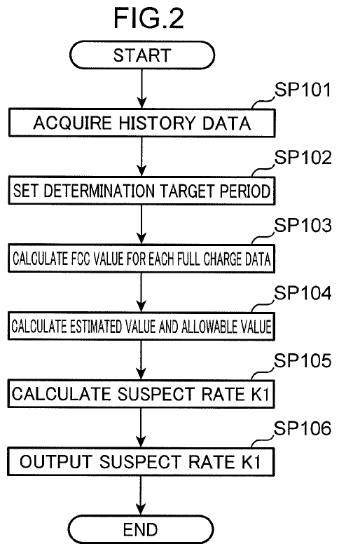

FIG. 2 is a flowchart illustrating the first example of the authenticity determination processing executed by the server device 5. Hereinafter, an example in which the battery pack 2A is a determination target will be described, but the same applies to a case where the battery pack 2B is a determination target.

When an execution command of the authenticity determination processing with the battery pack 2A as a determination target is input to the control unit 32, first, in step SP101, the acquisition unit 41 acquires the history data 52 related to the battery pack 2A by reading the history data 52 from the storage unit 33.

Next, in step SP102, the calculation unit 42 sets a determination target period. Hereinafter, an example of executing the authenticity determination processing of the battery with one month as a unit period will be described. However, the unit period is not limited to one month, and may be any period such as several weeks or several months.

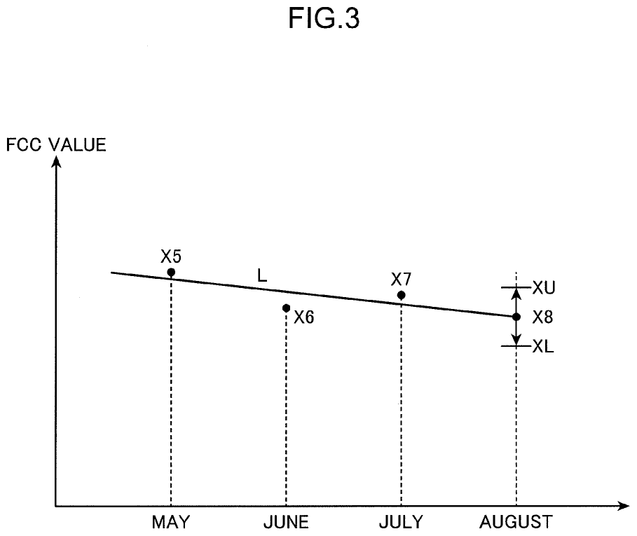

FIG. 3 is a view illustrating an example of a time series change in a full charge capacity value (FCC value) of the battery pack 2A. In the example illustrated in FIG. 3, it is assumed that May of this year is a shipping month of the battery pack 2A, and it has been determined that the battery pack 2A is a genuine product until July of the same year. In this case, the calculation unit 42 sets, as a determination target period (determination target month), August of the same year, which is the first undetermined month.

Next, in step SP103, the calculation unit 42 extracts all the history data (hereinafter referred to as “full charge data”) corresponding to the charging operation performed to the full charge state from among the history data 52 related to the battery pack 2A in the determination target month. The calculation unit 42 calculates an FCC value (first state quantity) for each of all the extracted full charge data. Any algorithm can be used as the algorithm for calculating the FCC value from the current value data and the voltage value data included in the full charge data. For example, association data associating the internal resistance ratio between an initial state and a deterioration state of the battery with the full charge capacity ratio between the initial state and the deterioration state is created in advance and stored in the storage unit. The calculation unit 42 estimates the internal resistance value of the battery based on current value data, voltage value data, and known map information. The calculation unit 42 calculates, from the related data, the full charge capacity ratio corresponding to the internal resistance ratio calculated from the estimated internal resistance value, thereby estimating the FCC value corresponding to each piece of the full charge data.

Next, in step SP104, the calculation unit 42 calculates an estimated value (second state quantity) of the FCC value of the battery pack 2A in the determination target month based on the history data 52 related to the battery pack 2A in the determined month. The calculation unit 42 calculates the FCC values by the algorithm similar to that described above for each of all the full charge data in each month from May to July, which is the determined month, and calculates average values X5 to X7 of a plurality of FCC values in each month. The calculation unit 42 derives, for example, an approximate straight line L from the plurality of average values X5 to X7 by using an arbitrary estimation algorithm such as approximation by a least squares method or a prediction model by machine learning, and applies the approximate straight line L to August, which is a determination target month, thereby calculating an estimated value X8 of the FCC value in August.

The calculation unit 42 calculates an allowable value for the estimated value of the FCC value in the determination target month based on the history data 52 in the most recent determined month of the determination target month. The calculation unit 42 calculates standard deviation σ by statistically processing the plurality of FCC values in July, for example, calculates an allowable upper limit value XU as a value in which 2×σ is added to the estimated value X8, and calculates an allowable lower limit value XL as a value 2×σ is subtracted from the estimated value X8.

Next, in step SP105, the determination unit 43 performs authenticity determination as to whether the battery pack 2A is a genuine product or an imitation product in the determination target month based on the first state quantity and the second state quantity. The determination unit 43 determines whether each of the plurality of FCC values as the first state quantity, for example, is included in an allowable range (that is, a range equal to or less than the allowable upper limit value XU and equal to or greater than the allowable lower limit value XL) including the estimated value X8 as the second state quantity. Then, as a ratio of the number (Y1) of FCC values exceeding the allowable upper limit value XU or below the allowable lower limit value XL to the total number (Z1) of the plurality of FCC values as the first state quantity, the determination unit 43 calculates a suspect rate K1 (=Y1/Z1×100) indicating the probability that the battery pack 2A is an imitation product.

Next, in step SP106, the output unit 44 outputs data indicating the suspect rate K1, which is a result of the authenticity determination by the determination unit 43. A manager of the battery management system can acquire, from the server device 5, data indicating the suspect rate K1 by accessing the server device 5 from a terminal operated by the manager via the communication network 4.

According to the first example, since it is possible to accurately calculate the FCC value of the battery pack 2A based on the history data 52 on charge and discharge of the battery pack 2A, it becomes possible to improve the accuracy of determination by performing authenticity determination of the battery pack 2A based on the FCC value of the battery pack 2A.

The suspect rate K1 indicating the probability that the battery pack 2A is an imitation product can be output as the result of the authenticity determination, instead of the alternative of whether the battery pack 2A is a genuine product or an imitation product.

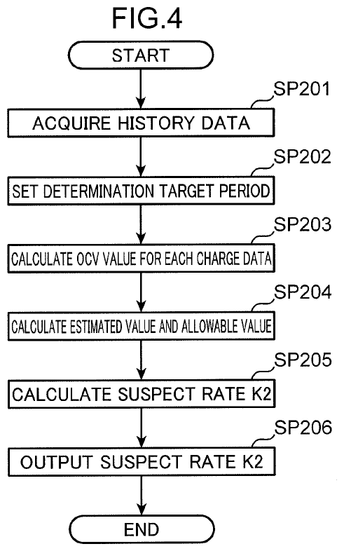

FIG. 4 is a flowchart illustrating the second example of the authenticity determination processing executed by the server device 5. Hereinafter, an example in which the battery pack 2A is a determination target will be described, but the same applies to a case where the battery pack 2B is a determination target.

When an execution command of the authenticity determination processing with the battery pack 2A as a determination target is input to the control unit 32, first, in step SP201, the acquisition unit 41 acquires the history data 52 related to the battery pack 2A, similarly to the first example.

Next, in step SP202, the calculation unit 42 sets a determination target period, similarly to the first example.

Next, in step SP203, the calculation unit 42 extracts all the history data (hereinafter referred to as “charge data”) corresponding to the charging operation of the battery pack 2A from among the history data 52 related to the battery pack 2A in the determination target month. The calculation unit 42 calculates, for each of all the extracted charge data, the open circuit voltage value (OCV value, first state quantity) in accordance with the remaining capacity rate (SOC) of the battery pack 2A. The calculation unit 42 can calculate the SOC by a current integration method, for example. The calculation unit 42 can handle the voltage value data included in the charge data approximately as an OCV value. The calculation unit 42 divides the SOC distribution range (for example, 40 to 100%) into a plurality of SOC regions by dividing the SOC distribution range by a predetermined pitch width (for example, 10%), and calculates, for each piece of charge data, an average value of the plurality of OCV values included in each SOC region as an OCV value corresponding to the SOC region.

Next, in step SP204, the calculation unit 42 calculates an estimated value (second state quantity) of the OCV value in accordance with the SOC of the battery pack 2A in the determination target month based on the history data 52 related to the battery pack 2A in the determined month.

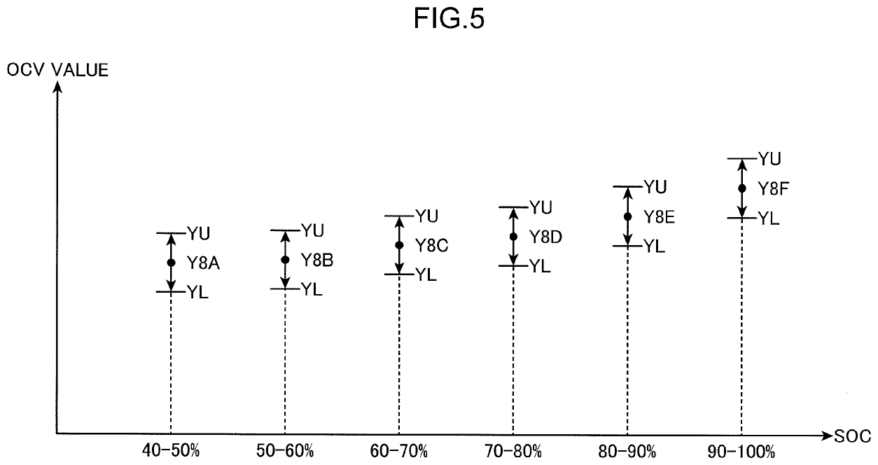

FIG. 5 is a view illustrating an example of distribution of OCV values in accordance with an SOC of the battery pack 2A. The calculation unit 42 calculates the OCV value in accordance with the SOC by the algorithm similar to that described above for each of all the charge data in each month from May to July, which is the determined month, and calculates the average value of the plurality of OCV values of the determined month in each SOC region as estimated values Y8A to Y8F of the OCV value in accordance with each SOC region.

The calculation unit 42 calculates an allowable value for the estimated value of the OCV value in the determination target month based on the history data 52 in the most recent determined month of the determination target month. The calculation unit 42 calculates, for each SOC region, standard deviation σ by statistically processing the plurality of OCV values in July, for example, calculates an allowable upper limit value YU for each SOC region as a value in which 2×σ is added to each of the estimated values Y8A to Y8F, and calculates an allowable lower limit value YL for each SOC region as a value in which 2×σ is subtracted from each of the estimated values Y8A to Y8F.

Next, in step SP205, the determination unit 43 performs authenticity determination as to whether the battery pack 2A is a genuine product or an imitation product in the determination target month based on the first state quantity and the second state quantity. The determination unit 43 determines whether each of the plurality of OCV values as the first state quantity, for example, is included in an allowable range (that is, a range equal to or less than the allowable upper limit value YU and equal to or greater than the allowable lower limit value YL) including each of the estimated values Y8A to Y8F as the second state quantity. Then, as a ratio of the number (Y2) of OCV values exceeding the allowable upper limit value YU or below the allowable lower limit value YL to the total number (Z2) of the plurality of OCV values as the first state quantity, the determination unit 43 calculates a suspect rate K2 (=Y2/Z2×100) indicating the probability that the battery pack 2A is an imitation product.

Next, in step SP206, the output unit 44 outputs data indicating the suspect rate K2, which is a result of the authenticity determination by the determination unit 43.

According to the second example, since it is possible to accurately calculate the OCV value in accordance with the SOC of the battery pack 2A based on the history data 52 on charge and discharge of the battery pack 2A, it becomes possible to improve the accuracy of determination by performing authenticity determination of the battery pack 2A based on the OCV value in accordance with the SOC of the battery pack 2A.

The suspect rate K2 indicating the probability that the battery pack 2A is an imitation product can be output as the result of the authenticity determination, instead of the alternative of whether the battery pack 2A is a genuine product or an imitation product.

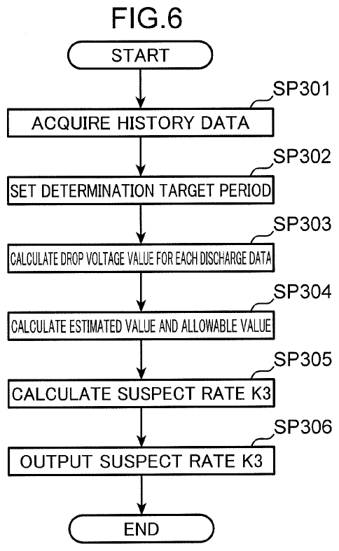

FIG. 6 is a flowchart illustrating the third example of the authenticity determination processing executed by the server device 5. Hereinafter, an example in which the battery pack 2A is a determination target will be described, but the same applies to a case where the battery pack 2B is a determination target.

When an execution command of the authenticity determination processing with the battery pack 2A as a determination target is input to the control unit 32, first, in step SP301, the acquisition unit 41 acquires the history data 52 related to the battery pack 2A, similarly to the first example.

Next, in step SP302, the calculation unit 42 sets a determination target period, similarly to the first example.

Next, in step SP303, the calculation unit 42 extracts all the history data (hereinafter referred to as “discharge data”) corresponding to the discharge operation of the battery pack 2A from among the history data 52 related to the battery pack 2A in the determination target month. The calculation unit 42 calculates, for each of all the extracted discharge data, a drop voltage value (first state quantity) in accordance with the SOC and the discharge current rate (ratio of the discharge current value to the maximum discharge current value) of the battery pack 2A.

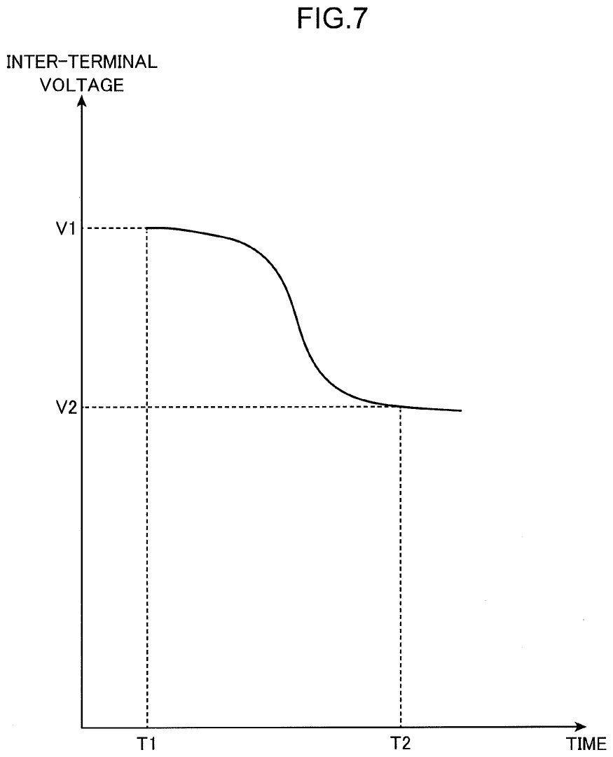

FIG. 7 is a view illustrating a voltage drop that occurs with discharge operation of the battery pack 2A. When the throttle of the vehicle 1A is opened at time T1, the discharge operation of the battery pack 2A is started, and when the voltage drop rate becomes equal to or less than a predetermined value (for example, 0.1 V/sec) at time T2, the voltage drop ends. A difference (=V1−V2) between an inter-terminal voltage value V1 of both poles (positive electrode and negative electrode) of the battery cell 15A at time T1 and an inter-terminal voltage value V2 at time T2 is a drop voltage value.

The calculation unit 42 can calculate the SOC by a current integration method, for example. The calculation unit 42 can handle the current value data included in the discharge data as a discharge current value. The calculation unit 42 can handle the voltage value data included in the discharge data as an inter-terminal voltage value. The calculation unit 42 divides the SOC distribution range (for example, 50 to 100%) into a plurality of SOC regions by dividing the SOC distribution range by a predetermined pitch width (for example, 10%). The calculation unit 42 divides the distribution range of the discharge current rate (for example, 50 to 100%) into a plurality of current rate regions by dividing the distribution range by a predetermined pitch width (for example, 10%). Upon detecting the voltage drop in each piece of discharge data, the calculation unit 42 calculates and records the drop voltage value in accordance with the SOC region and the current rate region according to the SOC and the discharge current rate of the battery pack 2A at that time.

Next, in step SP304, the calculation unit 42 calculates an estimated value (second state quantity) of the drop voltage value in accordance with the SOC and the discharge current rate of the battery pack 2A in the determination target month based on the history data 52 related to the battery pack 2A in the determined month.

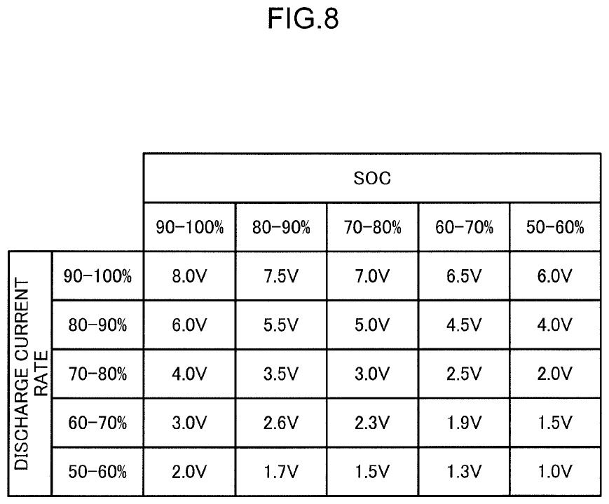

FIG. 8 is a view illustrating an example of distribution of the drop voltage value in accordance with the SOC and the discharge current rate of the battery pack 2A. The calculation unit 42 calculates the drop voltage value in accordance with the SOC and the discharge current rate by the algorithm similar to that described above for each of all the discharge data in each month from May to July, which is the determined month, and calculates the average value of the plurality of drop voltage values in the determined month in each SOC region and each current rate region as the estimated value of the drop voltage value in accordance with each SOC region and each current rate region.

The calculation unit 42 calculates an allowable value for the estimated value of the drop voltage value in the determination target month based on the history data 52 in the most recent determined month of the determination target month. The calculation unit 42 calculates, for each SOC region and current rate region, standard deviation σ by statistically processing the plurality of drop voltage values in July, for example, calculates an allowable upper limit value for each SOC region and current rate region as a value in which 2×σ is added to each estimated value, and calculates an allowable lower limit value for each SOC region and current rate region as a value in which 2×σ is subtracted from each estimated value.

Next, in step SP305, the determination unit 43 performs authenticity determination as to whether the battery pack 2A is a genuine product or an imitation product in the determination target month based on the first state quantity and the second state quantity. The determination unit 43 determines whether each of the plurality of drop voltage values as the first state quantity, for example, is included in an allowable range (that is, a range equal to or less than the allowable upper limit value and equal to or more than the allowable lower limit value) including each estimated value as the second state quantity. Then, as a ratio of the number (Y3) of drop voltage values exceeding the allowable upper limit value or below the allowable lower limit value to the total number (Z3) of the plurality of drop voltage values as the first state quantity, the determination unit 43 calculates a suspect rate K3 (=Y3/Z3×100) indicating the probability that the battery pack 2A is an imitation product.

Next, in step SP306, the output unit 44 outputs data indicating the suspect rate K3, which is a result of the authenticity determination by the determination unit 43.

According to the third example, since it is possible to accurately calculate the drop voltage value in accordance with the SOC and the discharge current rate of the battery pack 2A based on the history data 52 on charge and discharge of the battery pack 2A, it becomes possible to improve the accuracy of determination by performing authenticity determination of the battery pack 2A based on the drop voltage value in accordance with the SOC and the discharge current rate of the battery pack 2A. There is a case where the drop voltage value varies depending on the output of the vehicle mounted with the battery pack, and therefore the drop voltage value may be calculated separately for each type of vehicle.

The suspect rate K3 indicating the probability that the battery pack 2A is an imitation product can be output as the result of the authenticity determination, instead of the alternative of whether the battery pack 2A is a genuine product or an imitation product.

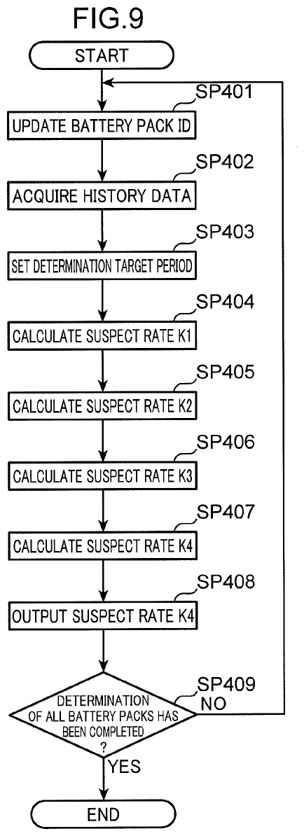

FIG. 9 is a flowchart illustrating the fourth example of the authenticity determination processing executed by the server device 5. This fourth example is a combination of the first to third examples. However, it is not necessary to combine all of the first to third examples, and an example other than the first to third examples may be combined.

When an execution command of the authenticity determination processing with all the battery packs managed by the server device 5 as a determination target is input to the control unit 32, first, in step SP401, the acquisition unit 41 updates the battery pack ID, thereby setting the battery pack ID of the battery pack 2A to be determined first.

Next, in step SP402, the acquisition unit 41 acquires the history data 52 related to the battery pack 2A, similarly to the first example.

Next, in step SP403, the calculation unit 42 sets a determination target period, similarly to the first example.

Next, in step SP404, the calculation unit 42 and the determination unit 43 calculate the suspect rate K1 similarly to steps SP103 to SP105 described above.

Next, in step SP405, the calculation unit 42 and the determination unit 43 calculate the suspect rate K2 similarly to steps SP203 to SP205 described above.

Next, in step SP406, the calculation unit 42 and the determination unit 43 calculate the suspect rate K3 similarly to steps SP303 to SP305 described above.

Next, in step SP407, the determination unit 43 calculates a suspect rate K4 by weighting the suspect rates K1 to K3 using coefficients W1 to W3 of equal to or greater than “0” as expressed by the following Equation (1).

K4=(W1×K1+W2×K2+W3×K3)/(W1+W2+W3): (1)

Next, in step SP408, the output unit 44 outputs data indicating the suspect rate K4, which is a result of the authenticity determination by the determination unit 43 with the battery pack 2A as the determination target.

Next, in step SP409, the acquisition unit 41 determines whether the authenticity determination processing with all the battery packs managed by the server device 5 as the determination target has been completed.

If there is an undetermined battery pack (step SP409: NO), next in step SP401, the acquisition unit 41 updates the battery pack ID, thereby setting the battery pack ID of the battery pack 2B to be determined next. Hereinafter, the processing in and after step SP402 is executed.

When the authenticity determination processing with all the battery packs as the determination target has been completed (step SP409: YES), the control unit 32 ends the processing.

### SUMMARY

According to the battery management system according to the present embodiment, the calculation unit 42 calculates the FCC value (first state quantity) indicating the state quantity of the battery pack 2A (battery) in the first period based on the history data 52 (first data) in the determination target period (first period). The calculation unit 42 calculates the FCC value (second state quantity) indicating the estimated value of the state quantity of the battery in the first period based on the history data 52 (second data) in the determined period (second period) before the first period. When the battery cell 15A of a genuine product is replaced with an imitation product, the first state quantity and the second state quantity greatly differ before and after replacement, and therefore by the determination unit 43 performing authenticity determination of the battery based on the first state quantity and the second state quantity, it is possible to detect that the battery cell 15A has been replaced. As a result, even when only the battery cell 15A is replaced with an imitation product, the battery can be correctly determined as an imitation product.

(First Modification)

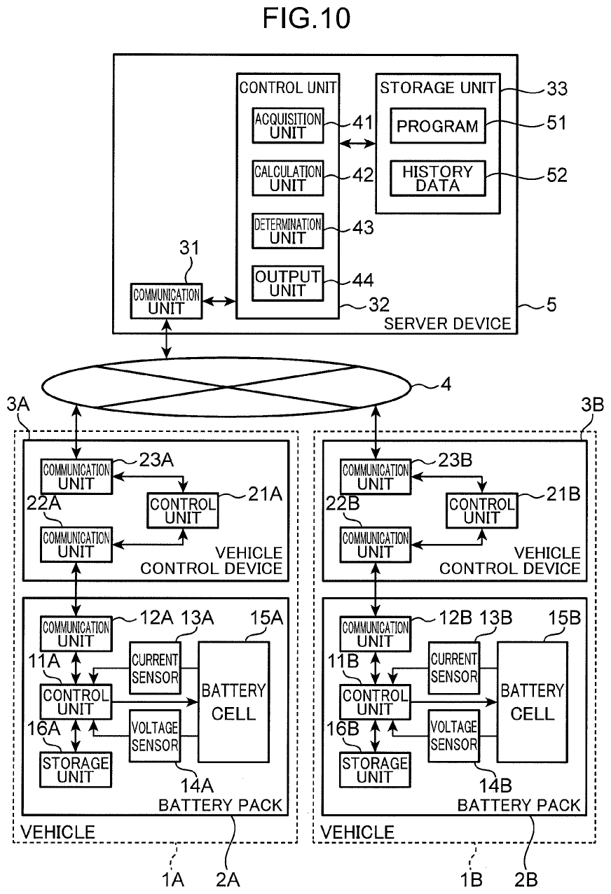

FIG. 10 is a view illustrating the first modification of the system configuration. In the present modification, the battery packs 2A and 2B include storage units 16A and 16B. The storage units 16A and 16B are configured using a semiconductor memory or the like.

Both the battery packs 2A and 2B and the server device 5 function as nodes of a blockchain, and the storage units 16A, 16B, and 33 of the respective nodes share the same history data 52. When the charge-discharge history is updated in any of the battery packs 2A and 2B, update information indicating the update content is transmitted to the other battery packs 2B and 2A and the server device 5 via the communication network 4, and the history data 52 is commonly updated in all the nodes.

According to the present modification, since it becomes difficult for a third party to falsify the history data 52, security of the system can be improved.

(Second Modification)

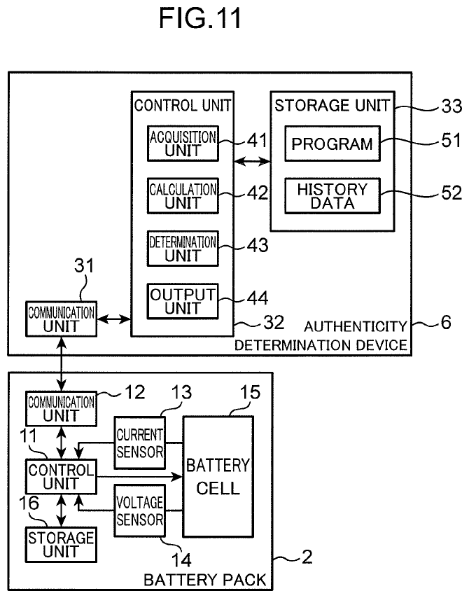

FIG. 11 is a view illustrating the second modification of the system configuration. In the present modification, the server device 5 such as a cloud server does not function as an authenticity determination device, but a local PC or a dedicated imitation product determiner functions as an authenticity determination device 6.

A battery pack 2 includes a control unit 11, a communication unit 12, a current sensor 13, a voltage sensor 14, a battery cell 15, and a storage unit 16. The storage unit 16 is configured using a semiconductor memory or the like. The communication unit 12 can communicate with the communication unit 31 of the authenticity determination device 6 in a wired or wireless manner.

When a charge-discharge current flows through the battery cell 15 along with the driving operation of the vehicle, current value data is input from the current sensor 13 to the control unit 11, and voltage value data is input from the voltage sensor 14 to the control unit 11. The control unit 11 inputs, to the storage unit 16, the history data 52 including the current value data and the voltage value data, and the storage unit 16 accumulates the history data 52.

When the battery pack 2 is taken out of the vehicle and connected to the authenticity determination device 6, the control unit 11 reads the history data 52 from the storage unit 16 and inputs the history data 52 to the communication unit 12. The communication unit 12 transmits the history data 52 to the authenticity determination device 6. The communication unit 31 of the authenticity determination device 6 receives the history data 52 and inputs the received history data 52 to the control unit 32. The control unit 32 stores the history data 52 into the storage unit 33. The control unit 32 executes the authenticity determination processing with the battery pack 2 as a determination target by a method similar to that in the above embodiment based on the history data 52 read from the storage unit 33.

According to the present modification, it becomes possible to achieve the authenticity determination processing targeting the battery pack 2 with a simple configuration using the local PC or the like as the authenticity determination device 6.

(Third Modification)

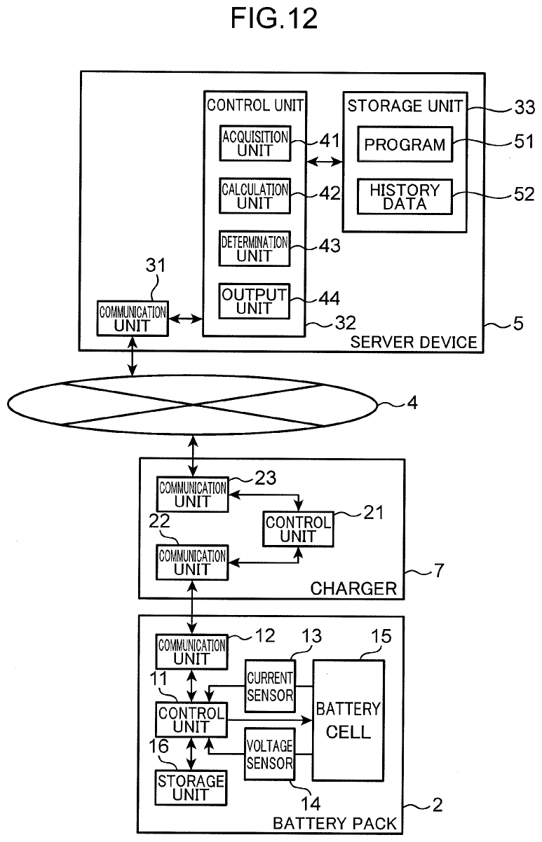

FIG. 12 is a view illustrating the third modification of the system configuration. In the present modification, a charger 7 for charging the battery pack 2 is connected to the server device 5 via the communication network 4.

When a charge-discharge current flows through the battery cell 15 along with the driving operation of the vehicle, current value data is input from the current sensor 13 to the control unit 11, and voltage value data is input from the voltage sensor 14 to the control unit 11. The control unit 11 inputs, to the storage unit 16, the history data 52 including the current value data and the voltage value data, and the storage unit 16 accumulates the history data 52.

When the battery pack 2 is taken out of the vehicle and connected to the charger 7, the control unit 11 reads the history data 52 from the storage unit 16 and inputs the history data 52 to the communication unit 12. The communication unit 12 transmits the history data 52 to the charger 7. A communication unit 22 of the charger 7 receives the history data 52 and inputs the received history data 52 into a control unit 21. The control unit 21 inputs the history data 52 to a communication unit 23. The communication unit 23 transmits the history data 52 to the server device 5. The communication unit 31 of the server device 5 receives the history data 52 and inputs the received history data 52 to the control unit 32. The control unit 32 stores the history data 52 into the storage unit 33. The control unit 32 executes the authenticity determination processing with the battery pack 2 as a determination target by a method similar to that in the above embodiment based on the history data 52 read from the storage unit 33.

According to the present modification, it becomes possible to achieve the authenticity determination processing for the battery pack 2 mounted on a vehicle not compatible with the plug-in method.

### INDUSTRIAL APPLICABILITY

The present disclosure is particularly useful for application to a battery management system that manages states of a plurality of battery packs mounted on a plurality of electric motorcycles or the like.

1. A battery authenticity determination method comprising, by a computer:
acquiring, regarding a battery having a battery cell, first data indicating a charge-discharge history in a first period and second data indicating a charge-discharge history in a second period before the first period;
calculating a first state quantity indicating a state quantity of the battery in the first period based on the first data;
calculating a second state quantity indicating an estimated value of the state quantity of the battery in the first period based on the second data;
performing authenticity determination as to whether the battery is a genuine product or an imitation product in the first period based on the first state quantity and the second state quantity; and
outputting a result of the authenticity determination.

2. The battery authenticity determination method according to claim 1, wherein the state quantity includes a full charge capacity.

3. The battery authenticity determination method according to claim 2, wherein
in calculating the first state quantity, a plurality of full charge capacity values are calculated by calculating the full charge capacity every time the battery is fully charged in the first period based on the first data,
in calculating the second state quantity, an estimated value of the full charge capacity of the battery in the first period and an allowable upper limit value and an allowable lower limit value having the estimated value therebetween are calculated based on the second data, and
in the authenticity determination, a ratio of a number of full charge capacity values exceeding the allowable upper limit value or below the allowable lower limit value to a total number of the plurality of full charge capacity values in the first period is calculated as a suspect rate that the battery is an imitation product.

4. The battery authenticity determination method according to claim 1, wherein the state quantity includes an open circuit voltage in accordance with a remaining capacity rate.

5. The battery authenticity determination method according to claim 4, wherein
in calculating the first state quantity, a plurality of open circuit voltage values is calculated by calculating the open circuit voltage every time the battery is charged in the first period based on the first data,
in calculating the second state quantity, an estimated value of the open circuit voltage in the first period and an allowable upper limit value and an allowable lower limit value having the estimated value therebetween are calculated based on the second data, and
in the authenticity determination, a ratio of a number of the open circuit voltage values exceeding the allowable upper limit value or below the allowable lower limit value to a total number of the plurality of open circuit voltage values in the first period is calculated as a suspect rate that the battery is an imitation product.

6. The battery authenticity determination method according to claim 1, wherein the state quantity includes a drop voltage in accordance with a remaining capacity rate and a discharge current rate.

7. The battery authenticity determination method according to claim 6, wherein
in calculating the first state quantity, a plurality of drop voltage values are calculated by calculating the drop voltage every time the battery is discharged in the first period based on the first data,
in calculating the second state quantity, an estimated value of the drop voltage in the first period and an allowable upper limit value and an allowable lower limit value having the estimated value therebetween are calculated based on the second data, and
in the authenticity determination, a ratio of a number of the drop voltage values exceeding the allowable upper limit value or below the allowable lower limit value to a total number of the plurality of drop voltage values in the first period is calculated as a suspect rate that the battery is an imitation product.

8. A battery authenticity determination device comprising:
an acquisition unit that acquires, regarding a battery having a battery cell, first data indicating a charge-discharge history in a first period and second data indicating a charge-discharge history in a second period before the first period;
a calculation unit that calculates a first state quantity indicating a state quantity of the battery in the first period based on the first data, and calculates a second state quantity indicating an estimated value of the state quantity of the battery in the first period based on the second data;
a determination unit that performs authenticity determination as to whether the battery is a genuine product or an imitation product in the first period based on the first state quantity and the second state quantity; and
an output unit that outputs a result of the authenticity determination.

9. A computer-readable recording medium recording a program for causing a computer to function as:
acquisition means for acquiring, regarding a battery having a battery cell, first data indicating a charge-discharge history in a first period and second data indicating a charge-discharge history in a second period before the first period,
calculation means for calculating a first state quantity indicating a state quantity of the battery in the first period based on the first data, and calculates a second state quantity indicating an estimated value of the state quantity of the battery in the first period based on the second data,
determination means for performing authenticity determination as to whether the battery is a genuine product or an imitation product in the first period based on the first state quantity and the second state quantity, and
output means for outputting a result of the authenticity determination.
